(19) United States
(12) Patent Application Publication
(10) Pub. No.: US 2024/0006410 A1
(43) Pub. Date: Jan. 4, 2024

(54) PROTECTION ELEMENT

(71) Applicant: ROHM CO., LTD., Kyoto (JP)

(72) Inventor: Satoshi TANAKA, Kyoto-shi (JP)

(21) Appl. No.: 18/255,726

(22) PCT Filed: Nov. 29, 2021
(86) PCT No.: PCT/JP2021/043698

§ 371 Date: Jun. 2, 2023

(30) Foreign Application Priority Data
Dec. 8, 2020 (JP) 2020-203231

(51) Int. Cl. H01L 27/088

(52) U.S. Cl. CPC H01L 27/088

(57) ABSTRACT

This protection element includes first to fourth switching elements, and a back gate guard ring surrounding the first to fourth switching elements. The back gate guard ring includes a first section, a second section, and a third section. The first section is disposed adjacent to a side of the first switching element opposite to the second switching element. The second section is disposed between the second switching element and the third switching element. The third section is disposed adjacent to a side of the fourth switching element opposite to the third switching element. A source of the first switching element is disposed closer to the first section than a gate of the first switching element. A source of the second switching element is disposed closer to the second section than a gate of the second switching element. A source of the third switching element is disposed closer to the second section than a gate of the third switching element.

### TECHNICAL FIELD

The present disclosure relates to a protection element.

### BACKGROUND ART

An n-type metal-oxide-semiconductor field-effect transistor (MOSFET) is a known protection element (refer to, for example, Patent Literature 1) used as a protection element used for protection from electrostatic discharge (ESD).

### CITATION LIST

### Patent Literature

Patent Literature 1: Japanese Laid-Open Patent Publication No. 2002-324842

### SUMMARY OF INVENTION

### Technical Problem

Miniaturization of electronic components have resulted in a demand for miniaturization of protection elements. Miniaturization of a protection element will, however, lower the hold voltage of the protection element. This may actuate the protection element at the operational voltage of the circuit that the protection element is protecting.

### Means for Solving the Problem

A protection element that solves the above problem includes switching elements formed by n-type MOSFETs and arranged in one direction in a state connected in parallel to each other, and a back gate guard ring surrounding the switching elements. The switching elements include a first switching element, a second switching element, a third switching element, and a fourth switching element that are arranged in this order. The back gate guard ring includes a first portion located adjacent to the first switching element at an opposite side of the second switching element, a second portion located between the second switching element and the third switching element, and a third portion located adjacent to the fourth switching element at an opposite side of the second switching element. A source of the first switching element is located closer to the first portion than a gate of the first switching element. A source of the second switching element is located closer to the second portion than a gate of the second switching element. A source of the third switching element is located closer to the second portion than a gate of the third switching element.

With this configuration, the back gate guard ring is located near the sources of the first to third switching elements. Thus, the hold voltage of the protection element can be increased, and erroneous actuation of the protection element can be avoided. Further, the second portion of the back gate guard ring is located between the source of the second switching element and the source of the third switching element. This allows the area of the protection element to be smaller than when the back gate guard ring separately surrounds the first to fourth switching elements. Thus, erroneous actuation of the protection element can be avoided, and the protection element can be reduced in size.

### Advantageous Effects of Invention

The protection element avoids erroneous actuation of the protection element and allows the protection element to be reduced in size.

### BRIEF DESCRIPTION OF THE DRAWINGS

FIG. 1 is a circuit diagram showing a first embodiment of a protection element.

FIG. 2 is a plan view showing part of the protection element.

FIG. 3 is a schematic cross-sectional view of the protection element shown in FIG. 2.

FIG. 4 is a graph illustrating the V-I characteristic of the protection element.

FIG. 5 is a plan view showing part of a protection element in a comparative example.

FIG. 6 is a schematic cross-sectional view of the protection element shown in FIG. 5.

FIG. 7 is a plan view showing part of a protection element in another comparative example.

FIG. 8 is a table showing the area and hold voltage of the protection element in the present embodiment and the protection element in the comparative example.

FIG. 9 is a plan view showing part of a modified example of the protection element.

FIG. 10 is a plan view showing part of a modified example of the protection element.

### DESCRIPTION OF EMBODIMENTS

An embodiment of a semiconductor device will now be described with reference to the drawings. The embodiment described below exemplifies a configuration and method for embodying a technical concept and is not intended to limit the material, shape, structure, arrangement, dimensions, and the like of each component to the description. In this specification, “at least one of A and B” should be understood to mean “only A, only B, or both A and B.”

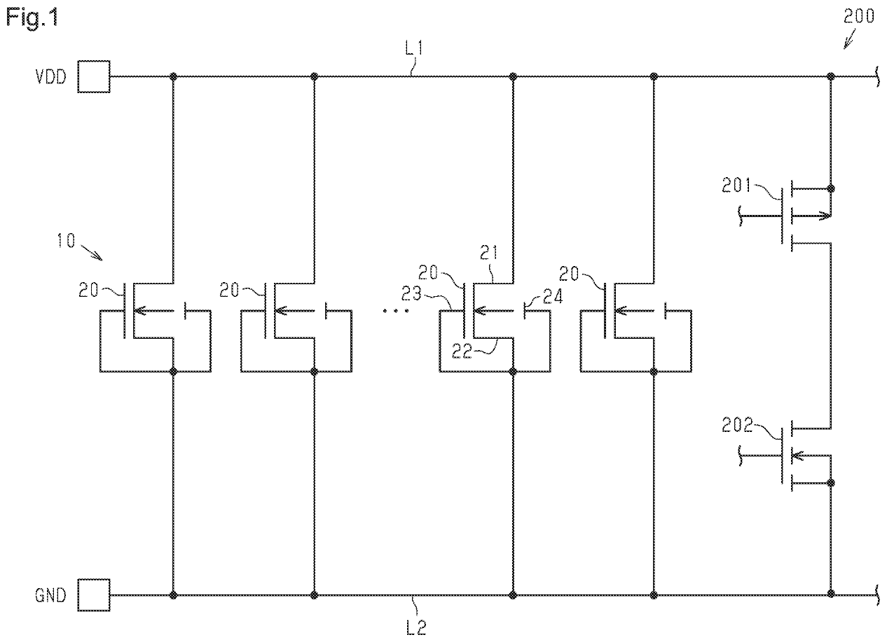

With reference to FIGS. 1 to 3, one embodiment of protection element 10 will now be described.

As shown in FIG. 1, the protection element 10 protects, for example, two switching elements 201 and 202 of an inverter device 200 from ESD. The switching element 201 is a high side switching element connected to a drive power supply, and the switching element 202 is a low side switching element. Examples of the switching elements 201 and 202 are transistors such as MOSFETs or IGBTs. In the description hereafter, MOSFETs are used as the switching elements 201 and 202. In the present embodiment, a p-type MOSFET is used as the switching element 201, and an n-type MOSFET is used as the switching element 202.

The switching element 201 includes a source connected to a first line L1 and a drain connected to the drain of the switching element 202. The source of the switching element 202 is connected to a second line L2. Thus, the switching element 201 and the switching element 202 are connected in series between the first line L1 and the second line L2. The gate of each of the switching elements 201 and 202 is connected to a gate driver (not shown). The first line L1 is connected to a power terminal VDD, which is connected to the drive power supply. The second line L2 is connected to a ground terminal GND.

The protection element 10 is disposed between the power terminal VDD, the ground terminal GND, and the two switching elements 201 and 202 to receive the current produced by static electricity that would flow through the two switching elements 201 and 202 in place of the two switching elements 201 and 202.

The protection element 10 includes switching elements 20. Each of the switching elements 20 is formed by an n-type MOSFET. The switching elements 20 are connected in parallel to each other. In one example, ten or more and twenty or less switching elements 20 are connected in parallel to one another. In the present embodiment, twelve switching elements 20 are connected in parallel to one another. Each switching element 20 includes a drain 21 connected to the first line L1, a source 22 connected to the second line L2, and a gate 23 connected to the source 22. Further, each switching element 20 includes a back gate 24 connected to the source 22 of the switching element 20 The source 22 of each switching element 20 is connected to the second line L2. Thus, each back gate 24 is set to ground potential.

The protection element 10 may be provided in a package separate from that of the two switching elements 201 and 202 or be provided in a package integrated with the two switching elements 201 and 202. In the present embodiment, the protection element 10 is provided in a package separate from that of the two switching elements 201 and 202 and thus packaged with the switching elements 20.

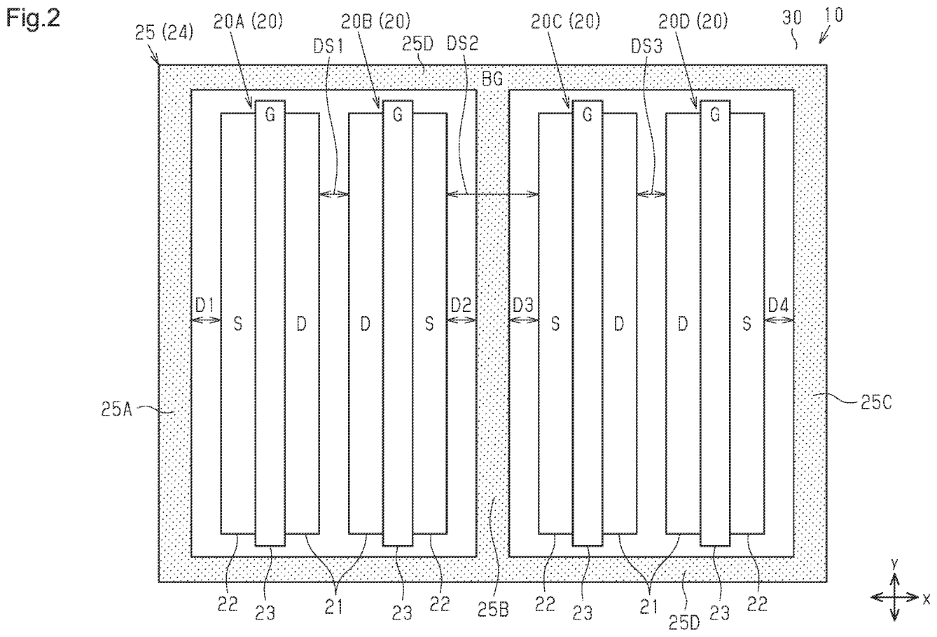

FIG. 2 shows one example of the switching elements 20. FIG. 2 illustrates the arrangement of four switching elements 20. The remaining eight switching elements 20 are arranged in the same manner as the arrangement shown in FIG. 2 and thus will now be described. The switching elements 20 other than the four switching elements 20 are not shown in FIG. 2.

In the description hereafter, for the sake of convenience, the four switching elements 20 will be referred to as the first switching element 20A, the second switching element 20B, the third switching element 20C, and the fourth switching element 20D. Further, in FIG. 2, to aid understanding of the drawing, D denotes the drain 21, S denotes the source 22, G denotes the gate 23, and BG denotes the back gate 24. For the same of convenience, the back gate 24 is shaded.

As shown in FIG. 2, the switching elements 20A to 20D are formed on a semiconductor substrate 30. FIG. 2 is a plan view of the semiconductor substrate 30 taken in a thickness direction. One example of the semiconductor substrate 30 is a silicon (Si) substrate. The switching elements 20A to 20D are arranged in one direction. In the description hereafter, the direction in which the switching elements 20A to 20D are arranged is referred to as the x-direction, the thickness direction of the semiconductor substrate 30 is referred to as the z-direction, and the direction orthogonal to both of the x-direction and the z-direction is referred to as the y-direction. Further, plan view will refer to a state viewed in the z-direction.

As shown in FIG. 2, the switching elements 20A to 20D are located at the same position in the y-direction and separated from one another in the x-direction. In the present embodiment, the first switching element 20A, the second switching element 20B, the third switching element 20C, and the fourth switching element 20D are arranged in this order in the x-direction. Thus, the second switching element 20B and the third switching element 20C are located between the first switching element 20A and the fourth switching element 20D in the x-direction. The second switching element 20B is located closer to the first switching element 20A than the third switching element 20C.

The drain 21, the source 22, and the gate 23 of each of the switching elements 20A to 20D are arranged in the x-direction. Thus, the arrangement direction of the drain 21, the source 22, and the gate 23 in each of the switching elements 20A to 20D is the same as the arrangement direction of the switching elements 20A to 20D.

In the present embodiment, in the first switching element 20A, the source 22, the gate 23, and the drain 21 are arranged in this order. In the second switching element 20B, the drain 21, the gate 23, and the source 22 are arranged in order. Thus, the drain 21 of the first switching element 20A is located adjacent to the drain 21 of the second switching element 20B in the x-direction. Further, the source 22 of the first switching element 20A is located most distant from the source 22 of the second switching element 20B.

The arrangement of the drain 21, the source 22, and the gate 23 in the third switching element 20C and the fourth switching element 20D is the same as that in the first switching element 20A and the second switching element 20B. More specifically, in the third switching element 20C, the source 22, the gate 23, and the drain 21 are arranged in this order. In the fourth switching element 20D, the drain 21, the gate 23, and the source 22 are arranged in this order. Thus, the source 22 of the third switching element 20C is located adjacent to the source 22 of the second switching element 20B in the x-direction.

The drain 21, the source 22, and the gate 23 of each of the switching elements 20A to 20D are located at the same position in the y-direction and arranged in the x-direction.

The drain 21, the source 22, and the gate 23 of each of the switching elements 20A to 20D each have the form of a strip extending in the y-direction. The length of the drain 21 in the y-direction is equal to the length of the source 22 in the y-direction. The length of the gate 23 in the y-direction is greater than the lengths of the drain 21 and the source 22 in the y-direction. The two ends of the gate 23 in the y-direction extend beyond the drain 21 and the source 22 in the y-direction, in plan view.

As shown in FIG. 2, the protection element 10 includes a back gate guard ring 25 surrounding the switching elements 20. The back gate guard ring 25 shown in FIG. 2 surrounds the switching elements 20A to 20D and includes the back gate 24 of each of the switching elements 20A to 20D. Thus, the back gate guard ring 25 serves as a common back gate 24 shared by the switching elements 20A to 20D.

The back gate guard ring 25 includes a first portion 25A located adjacent to the first switching element 20A at an opposite side of the second switching element 20B, a second portion 25B located between the second switching element 20B and the third switching element 20C, and a third portion 25C located adjacent to the fourth switching element 20D at an opposite side of the third switching element 20C. The first to third portions 25A to 25C each have the form of a strip extending in the y-direction, in plan view.

The source 22 of the first switching element 20A is located closer to the first portion 25A than the gate 23 of the first switching element 20A, in plan view. The drain 21 of the first switching element 20A is located closer to the second portion 25B than the gate 23 of the first switching element 20A. The drain 21 of the second switching element 20B is located closer to the first portion 25A than the gate 23 of the second switching element 20B. The source 22 of the second switching element 20B is located closer to the second portion 25B than the gate 23 of the second switching element 20B. The source 22 of the third switching element 20C is located closer to the second portion 25B than the gate 23 of the third switching element 20C. The drain 21 of the third switching element 20C is located closer to the third portion 25C than the gate 23 of the third switching element 20C. The drain 21 of the fourth switching element 20D is located closer to the second portion 25B than the gate 23 of the fourth switching element 20D. The source 22 of the fourth switching element 20D is located closer to the third portion 25C than the gate 23 of the fourth switching element 20D.

As described above, in the first switching element 20A, the source 22, the gate 23, and the drain 21 are arranged in this order from the first portion 25A toward the second portion 25B in the x-direction. In the second switching element 20B, the drain 21, the gate 23, and the source 22 are arranged in this order from the first portion 25A toward the second portion 25B in the x-direction. In the third switching element 20C, the source 22, the gate 23, and the drain 21 are arranged in this order from the second portion 25B toward the third portion 25C in the x-direction. In the fourth switching element 20D, the drain 21, the gate 23, and the source 22 are arranged in this order from the second portion 25B toward the third portion 25C in the x-direction.

As shown in FIG. 2, the first portion 25A is separated from the source 22 of the first switching element 20A in the x-direction. The second portion 25B is separated from both of the source 22 of the second switching element 20B and the source 22 of the third switching element 20C in the x-direction. The third portion 25C is separated from the source 22 of the fourth switching element 20D in the x-direction.

The back gate guard ring 25 further includes two fourth portions 25D connecting the first to third portions 25A to 25C at their ends in the y-direction. The two fourth portions 25D each have the form of a strip extending in the x-direction, in plan view. The two fourth portions 25D are separated from each of the switching elements 20A to 20D in the y-direction.

The first portion 25A, the second portion 25B, and the two fourth portions 25D surround the first switching element 20A and the second switching element 20B. The second portion 25B, the third portion 25C, and the two fourth portions 25D surround the third switching element 20C and the fourth switching element 20D.

As shown in FIG. 2, in the present embodiment, the first to third portions 25A to 25C each have the form of a single strip extending in the y-direction, in plan view. In other words, the first portion 25A has the form of a single strip extending in a direction orthogonal to the arrangement direction of the switching elements 20, in plan view. The second portion 25B has the form of a single strip extending in the direction orthogonal to the arrangement direction of the switching elements 20. The third portion 25C has the form of a single strip extending in the direction orthogonal to the arrangement direction of the switching elements 20. A direction will be orthogonal to the arrangement direction of the switching elements 20 as long as the angle, in plan view, is 85° or greater and 95° or less between the direction in which the first portion 25A extends and the arrangement direction of the switching elements 20. A direction will be orthogonal to the arrangement direction of the switching elements 20 as long as the angle, in plan view, is 85° or greater and 95° or less between the direction in which the second portion 25B extends and the arrangement direction of the switching elements 20. A direction will be orthogonal to the arrangement direction of the switching elements 20 as long as the angle, in plan view, is 85° or greater and 95° or less between the direction in which the third portion 25C extends and the arrangement direction of the switching elements 20. The arrangement direction of the switching elements 20 may be set, for example, in conformance with a line segment connecting the y-direction center of the gate 23 in each of the switching elements 20.

The single second portion 25B is located between the second switching element 20B and the third switching element 20C. Thus, the second portion 25B is the back gate guard ring 25 commonly shared by the source 22 of the second switching element 20B and the source 22 of the third switching element 20C.

The positional relationship of the back gate guard ring 25 and each of the switching elements 20A to 20D will now be described.

The source 22 of each of the switching elements 20A to 20D is parallel to the first to third portions 25A to 25C, in plan view. More specifically, the distance in the x-direction between the source 22 of the first switching element 20A and the first portion 25A is constant in the y-direction. The distance in the x-direction between the source 22 of the second switching element 20B and the second portion 25B is constant in the y-direction. The distance in the x-direction between the source 22 of the third switching element 20C and the second portion 25B is constant in the y-direction. The distance in the x-direction between the source 22 of the fourth switching element 20D and the third portion 25C is constant in the y-direction.

The second portion 25B is located between the second switching element 20B and the third switching element 20C. Thus, distance DS2 between the second switching element 20B and the third switching element 20C is greater than distance DS1 between the first switching element 20A and the second switching element 20B. Further, distance DS2 is greater than distance DS3 between the third switching element 20C and the fourth switching element 20D.

Distance D1 between the source 22 of the first switching element 20A and the first portion 25A is equal to distance D2 between the source 22 of the second switching element 20B and the second portion 25B. As long as the difference between distance D1 and distance D2 is less than or equal to 10% of distance D1, distance D1 will be equal to distance D2.

Distance D3 between the source 22 of the third switching element 20C and the second portion 25B is equal to distance D2 between the source 22 of the second switching element 20B and the second portion 25B. As long as the difference between distance D3 and distance D2 is less than or equal to 10% of distance D3, distance D3 will be equal to distance D2.

Distance D4 between the source 22 of the fourth switching element 20D and the third portion 25C is equal to distance D2 between the source 22 of the second switching element 20B and the second portion 25B. Thus, distances D1 to D4 are equal to one another. As long as the difference between distance D4 and distance D2 is less than or equal to 10% of distance D4, distance D4 will be equal to distance D2. Thus, distance D1, distance D2, distance D3, and distance D4 are equal to one another.

Distances D1, D3, and D4 are equal to distance D2. Thus, distances D1 to D4 are equal to one another. Instead of distance D2, another distance may be used as a basis. In one example, distances D1 to D4 are equal to one another because distances D2 to D4 are equal to distance D1. As long as the maximum difference between distances D1 to D4 is less than or equal to 10% of distance D1, distances D1 to D4 will be equal to one another. Although distance D1 is used as a basis, any of distances D2 to D4 may be used instead.

In the present embodiment, distances D1 to D4 are each equal to the distance between the drain 21 of the first switching element 20A and the drain 21 of the second switching element 20B, that is, distance DS1 between the first switching element 20A and the second switching element 20B. Further, each of distances D1 to D4 is equal to the distance between the drain 21 of the third switching element 20C and the drain 21 of the fourth switching element 20D, that is, distance DS3 between the third switching element 20C and the fourth switching element 20D. The relationship of distances D1 to D4 and distances DS1 and DS3 may be freely changed. In one example, distances DS1 and DS3 may be less than distances D1 to D4.

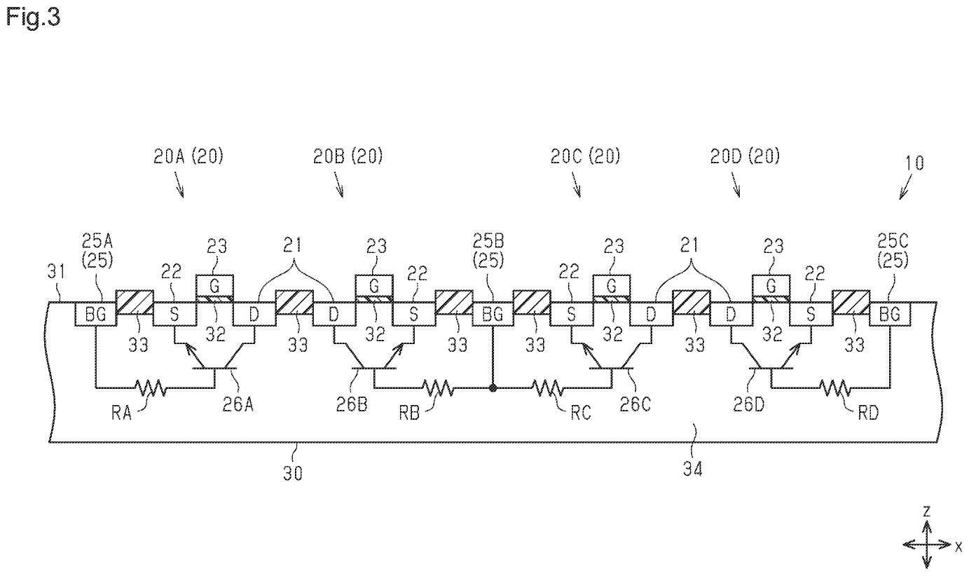

FIG. 3 is a cross-sectional view of each of the switching elements 20A to 20D.

As shown in FIG. 3, the semiconductor substrate 30 is a Si substrate including a p⁻ type region 34. The p⁻ type region 34 is, for example, a well region formed in the semiconductor substrate 30. The semiconductor substrate 30 includes a surface 31 on which the drain 21 and the source 22 of each of the switching elements 20A to 20D and the back gate guard ring 25 is formed. The drain 21 and the source 22 are each formed by an n⁺ type well region. The back gate guard ring 25 is formed by a p⁺ type well region.

Further, the gate 23 of each of the switching elements 20A to 20D is formed on the surface 31 of the semiconductor substrate 30 with an oxide film 32 in between. One example of the oxide film 32 is silicon oxide (SiO₂). Thus, the surface 31 of the semiconductor substrate 30 includes a plurality of oxide films 32. The oxide films 32 are separated from one another in the x-direction. Each oxide film 32 is formed between a drain 21 and a source 22. A gate 23 is formed on each oxide film 32.

Element isolation zones 33 are formed between the source 22 of the first switching element 20A and the first portion 25A of the back gate guard ring 25, between the drain 21 of the first switching element 20A and the drain 21 of the second switching element 20B, between the source 22 of the second switching element 20B and the second portion 25B, between the source 22 of the third switching element 20C and the second portion 25B, between the drain 21 of the third switching element 20C and the drain 21 of the fourth switching element 20D, and between the source 22 of the fourth switching element 20D and the third portion 25C. Each element isolation zone 33 is, for example, STI or LOCOS.

As shown in FIG. 3, the drain 21 (n⁺) and the source 22 (n⁺) of the first switching element 20A and the p-type region 34 of the semiconductor substrate 30 form a first parasitic transistor 26A. The base of the first parasitic transistor 26A is connected to the first portion 25A of the back gate guard ring 25. A resistor RA between the base of the first parasitic transistor 26A and the first portion 25A is a resistance component of the p⁻ type region 34.

The drain 21 (n⁺) and the source 22 (n⁺) of the second switching element 20B and the p⁻ type region 34 form a second parasitic transistor 26B. The drain 21 (n⁺) and the source 22 (n⁺) of the third switching element 20C and the p⁻ type region 34 form a third parasitic transistor 26C. The base of each of the parasitic transistors 26B and 26C is connected to the second portion 25B of the back gate guard ring 25. A resistor RB between the base of the second parasitic transistor 26B and the second portion 25B and a resistor RC between the base of the third parasitic transistor 26C and the second portion 25B are resistance components of the p⁻ type region 34.

The drain 21 (n⁺) and the source 22 (n⁺) of the fourth switching element 20D and the p⁻ type region 34 form a fourth parasitic transistor 26D. The base of the fourth parasitic transistor 26D is connected to the third portion 25C of the back gate guard ring 25. A resistor RD between the base of the fourth parasitic transistor 26D and the third portion 25C is a resistance component of the p⁻ type region 34.

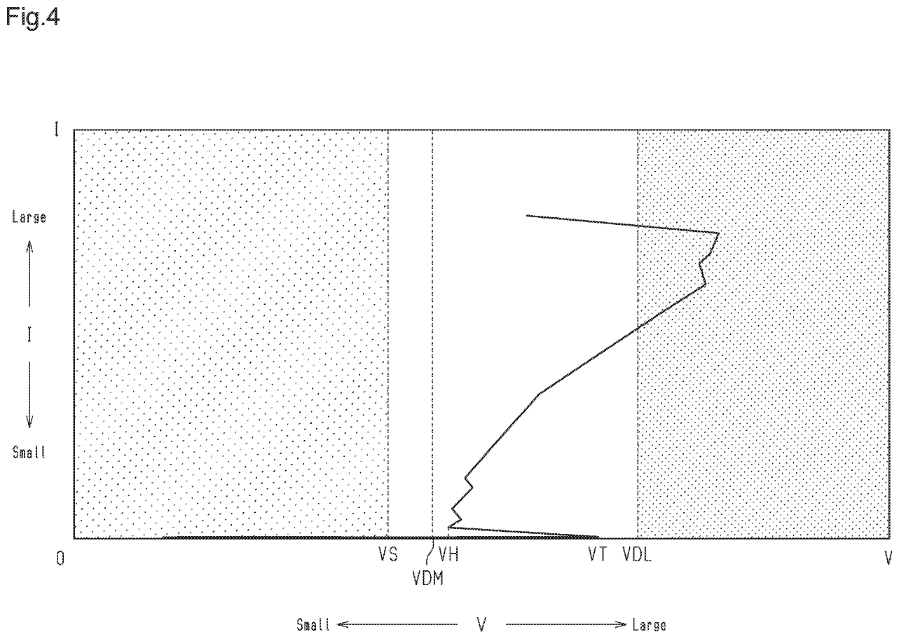

The solid line in the graph of FIG. 4 indicates the I-V characteristic of the protection element 10. In FIG. 4, the shaded region in the voltage range of 0 V to VS indicates the operational range of each of the switching elements 201 and 202 (refer to FIG. 1). The shaded region where the voltage is voltage VDL or greater indicates the region where a failure will occur in each of the switching elements 201 and 202.

As shown in FIG. 4, when the voltage V rises between line L1 and line L2 (refer to FIG. 1), leakage current flows through the back gate guard ring 25 (refer to FIG. 3). This increases the potential at the back gate guard ring 25. When the voltage V reaches a predetermined voltage VT, the parasitic transistors 26A to 26D (refer to FIG. 3) are connected. Snapback occurs when the parasitic transistors 26A to 26D are connected. This decreases the voltage V to the hold voltage V. Then, current corresponding to the voltage V flows through the protection element 10.

Operation

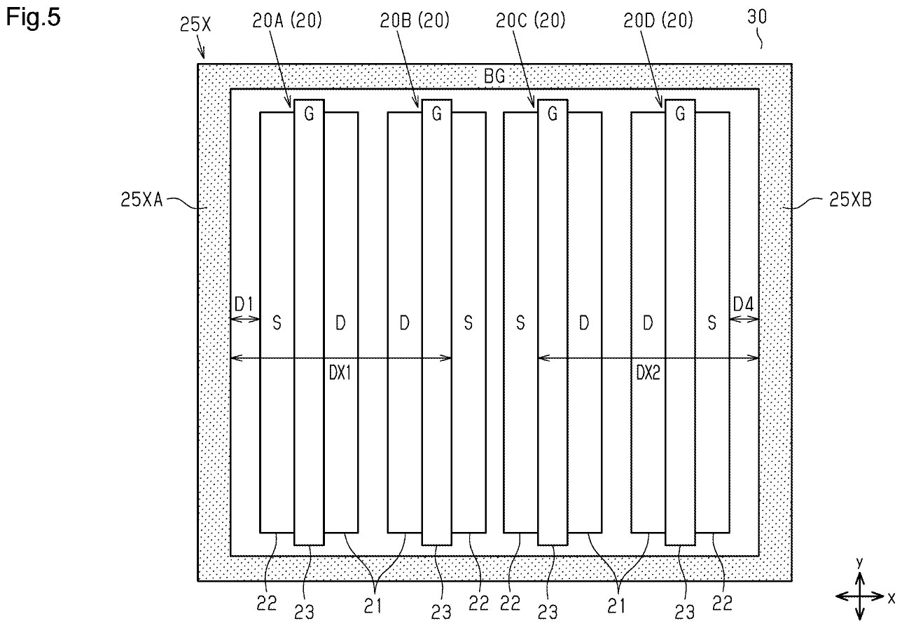

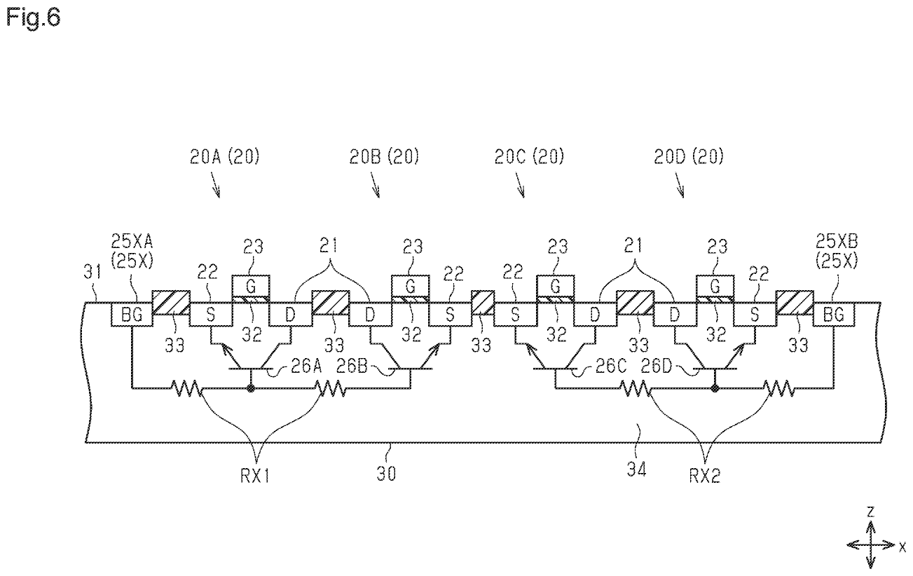

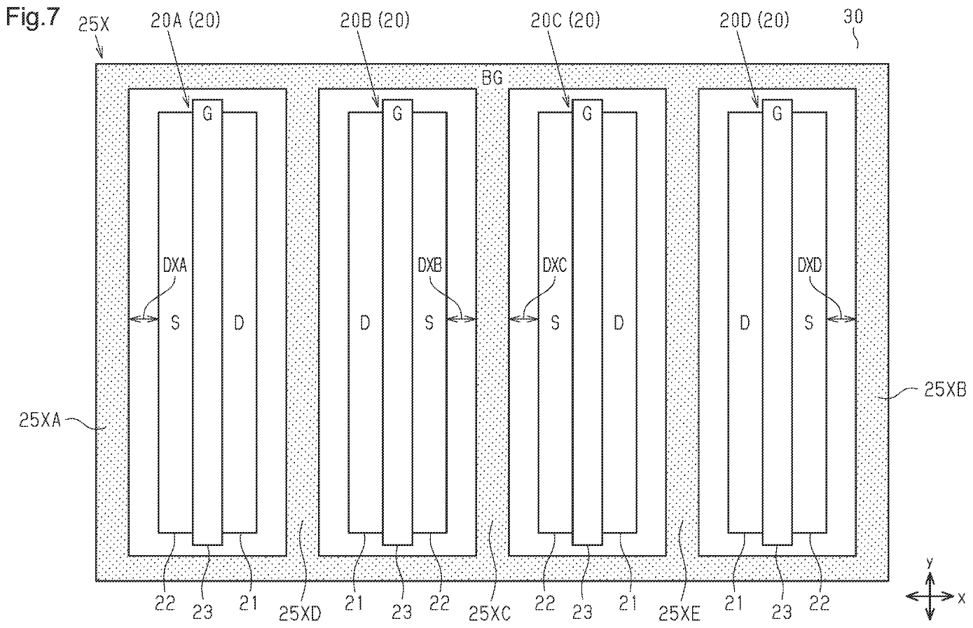

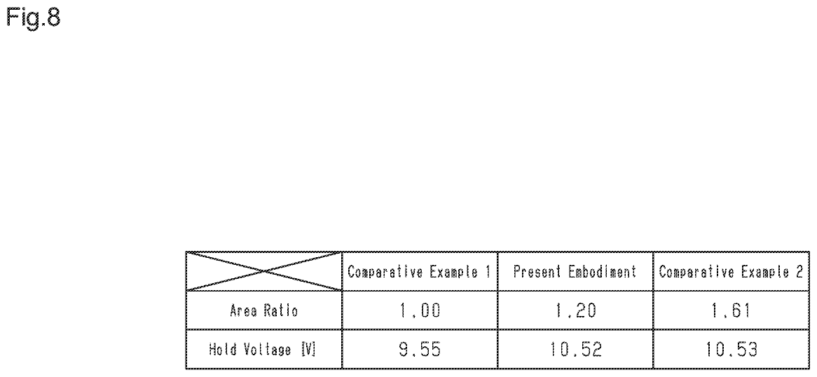

With reference to FIGS. 4 to 8, the operation of the protection element 10 in the present embodiment will now be described. In FIG. 8, comparative example 1 is the protection element of the comparative example shown in FIGS. 5 and 6, and comparative example 2 is the protection element of the comparative example shown in FIG. 7.

The voltage V between line L1 and line L2 is varied in accordance with the ESD. The protection element 10 protects the switching elements 201 and 202 from the varying voltage V. More specifically, the protection element 10 is required to be actuated so that the voltage V will be less than a first voltage VDL that is the lower limit value from which the switching elements 201 and 202 starts to break. Further, in order to avoid actuation of the protection element 10 in the operational voltage range of the switching elements 201 and 202, the protection element 10 is required to be actuated at a voltage greater than the second voltage VDM, which is greater than the upper limit value of the voltage range. Thus, the protection element 10 is required to be actuated in a voltage range that is greater than the second voltage VDM and less than the first voltage VDL. The second voltage VDM is also referred to as the absolute maximum voltage.

In order to use space efficiently, the protection element 10 needs to be miniaturized. Miniaturization of the protection element 10 may lower the hold voltage V to less than or equal to the second voltage VDM.

Thus, the hold voltage V has to be increased. To increase the hold voltage V, the resistance of the resistance component in the p⁻ type region 34 between the source 22 and the back gate 24 has to be increased. It is understood that the resistance is proportional to the distance between the source 22 and the back gate 24. Thus, as shown in FIG. 5, formation of the back gate guard ring 25X collectively surrounding the switching elements 20A to 20D increases distance DX1 between the source 22 of the second switching element 20B and a first end 25XA of the back gate guard ring 25X and distance DX2 between the source 22 of the third switching element 20C and a second end 25XB of the back gate guard ring 25X. As shown in FIG. 6, resistance RX1 of the p⁻ type region 34 between the source 22 of the second switching element 20B and the first end 25XA of the back gate guard ring 25X is the sum of the resistance component of the p⁻ type region 34 between the base of the second parasitic transistor 26B and the base of the first parasitic transistor 26A and the resistance component of the p⁻ type region 34 between the first parasitic transistor 26A and the first end 25XA of the back gate guard ring 25X. Further, resistance RX2 of the p⁻ type region 34 between the source 22 of the third switching element 20C and the second end 25XB of the back gate guard ring 25X is the sum of the resistance component of the p⁻ type region 34 between the base of the third parasitic transistor 26C and the base of the fourth parasitic transistor 26D and the resistance component of the p⁻ type region 34 between the base of the fourth parasitic transistor 26D and the second end 25XB of the back gate guard ring 25X. In this manner, the resistances RX1 and RX2 are increased. As shown in FIG. 8, this decreases the hold voltage V.

To raise the hold voltage V, for example, the back gate guard ring may be increased in area. For example, as shown in FIG. 7, a back gate guard ring 25X may be formed to surround each of the switching elements 20A to 20D. This will shorten each of distance DXA between the first end 25XA of the back gate guard ring 25X and the source 22 of the first switching element 20A, distance DXB between a first intermediate portion 25XC of the back gate guard ring 25X and the source 22 of the second switching element 20B, distance DXC between the first intermediate portion 25XC and the source 22 of the third switching element 20C, and distance DXD between the second end 25XB of the back gate guard ring and the source 22 of the fourth switching element 20D. As a result, as shown in FIG. 8, the hold voltage V (hold voltage V of comparison example 2) will become higher than the hold voltage V of the protection element of FIG. 5 (comparison example 1).

The back gate guard ring 25X shown in FIG. 7, however, includes a second intermediate portion 25XD between the switching element 20A and the switching element 20B and a third intermediate portion 25XE between the switching element 20C and the switching element 20D. Thus, as shown in FIG. 8, the area ratio of the protection element of comparative example 2 shown in FIG. 7 to the protection element of comparative example 1 shown in FIG. 5 is 1.61. In this manner, the area of the protection element in comparative example 2 is greater than the area of the protection element in comparative example 1.

In addition, the second intermediate portion 25XD is located between the drain 21 of the first switching element 20A and the drain 21 of the second switching element 20B. Further, the third intermediate portion 25XE is located between the drain 21 of the third switching element 20C and the drain 21 of the fourth switching element 20D. The two intermediate portions 25XD and 25XE substantially do not contribute to improvement of the hold voltage V.

In this respect, in the present embodiment, as shown in FIG. 2, the back gate guard ring 25 includes the first portion 25A located adjacent to the source 22 of the first switching element 20A, the second portion 25B located between the source 22 of the second switching element 20B and the source 22 of the third switching element 20C, and the third portion 25C located adjacent to the source 22 of the fourth switching element 20D. The back gate guard ring 25 of the present embodiment is less the second intermediate portion 25XD and the third intermediate portion 25XE of the back gate guard ring 25X shown in FIG. 7. Thus, as shown in FIG. 8, the area ratio of the protection element 10 of the present embodiment to the protection element of comparative example 1 shown in FIG. 5 is smaller than the area ratio of the protection element of comparative example 2 shown in FIG. 7 to the protection element of comparative example 1. Further, the hold voltage V of the protection element 10 in the present embodiment is about the same as the hold voltage V of the protection element in comparative example 2.

Advantages

The protection element 10 of the present embodiment has the advantages described below.

(1) The protection element 10 includes the switching elements 20, which are formed by n-type MOSFETs and arranged in one direction in a state connected in parallel to each other, and the back gate guard ring 25, which surrounds the switching elements 20. The switching elements 20 include the first switching element 20A, the second switching element 20B, the third switching element 20C, and the fourth switching element 20D that are arranged in this order. The back gate guard ring 25 includes the first portion 25A located adjacent to the first switching element 20A at the opposite side of the second switching element 20B, the second portion 25B located between the second switching element 20B and the third switching element 20C, and the third portion 25C located adjacent to the fourth switching element 20D at the opposite side of the third switching element 20C. The source 22 of the first switching element 20A is located closer to the first portion 25A than the gate 23 of the first switching element 20A. The source 22 of the second switching element 20B is located closer to the second portion 25B than the gate 23 of the second switching element 20B. The source 22 of the third switching element 20C is located closer to the second portion 25B than the gate 23 of the third switching element 20C.

With this configuration, the back gate guard ring 25 is located near the sources 22 of the first to third switching elements 20A to 20C. Thus, the hold voltage V of the protection element 10 can be increased, and erroneous actuation of the protection element 10 can be avoided. Further, the second portion 25B of the back gate guard ring 25 is located between the source 22 of the second switching element 20B and the source 22 of the third switching element 20C. As shown in FIG. 7, this allows the area of the protection element 10 to be smaller than when the back gate guard ring surrounds each of the switching elements 20A to 20D. Thus, erroneous actuation of the protection element 10 can be avoided, and the protection element 10 can be reduced in size.

(2) Distance D1 between the source 22 of the first switching element 20A and the first portion 25A of the back gate guard ring 25, distance D2 between the source 22 of the second switching element 20B and the second portion 25B, distance D3 between the source 22 of the third switching element 20C and the second portion 25B, and distance D4 between the source 22 of the fourth switching element 20D and the third portion 25C are equal.

With this configuration, current does not flow in a concentrated manner to any certain one of the switching elements 20A to 20D. Thus, the tolerable current of the protection element 10 will not be decreased.

(3) The second portion 25B of the back gate guard ring 25 has the form of a single strip extending in the direction (the y-direction) orthogonal to the arrangement direction (the x-direction) of the switching elements 20, in plan view.

This configuration allows the area of the protection element 10, in plan view, to be smaller than that when a back gate guard ring includes more than one second portion 25B. Thus, the protection element 10 can be reduced in size.

(4) The switching elements 20A to 20D each include a separate drain 21.

This configuration allows the drain 21 to have a greater volume than when the first switching element 20A and the second switching element 20B share a common drain and the third switching element 20C and the fourth switching element 20D share a common drain. Thus, the tolerable current of the protection element 10 can be increased.

Modified Examples

The embodiments described above exemplify, without any intention to limit, applicable forms of a protection element according to this disclosure. The protection element in accordance with this disclosure may be modified from the embodiment described above. For example, the configuration in the above embodiment may be replaced, changed, or omitted in part or include an additional element. The modified examples described below may be combined as long as there is no technical contradiction. In the modified examples described hereafter, same reference characters are given to those components that are the same as the corresponding components of the above embodiments. Such components will not be described in detail.

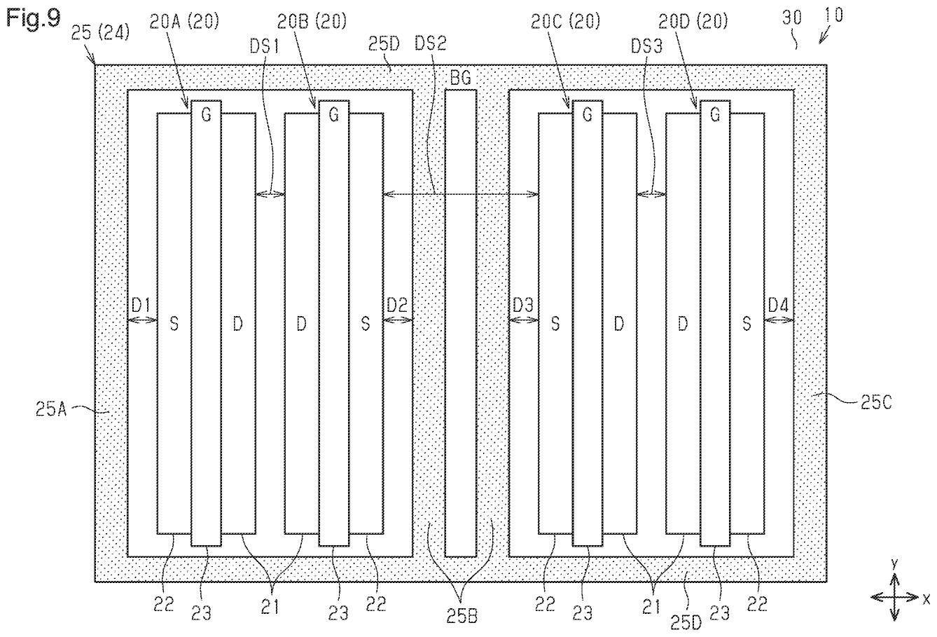

In the above embodiment, the back gate guard ring 25 may include more than one second portion 25B. In one example, as shown in FIG. 9, the back gate guard ring 25 includes two second portions 25B separated from each other in the x-direction. In this case, distance D2 between the second portion 25B located adjacent to the second switching element 20B and the source 22 of the second switching element 20B is equal to distance D3 between the second portion 25B located adjacent to the third switching element 20C and the source 22 of the third switching element 20C. Distances D2 and D3 are equal to both of distance D1 between the source 22 of the first switching element 20A and the first portion 25A of the back gate guard ring 25 and distance D4 between the source 22 of the fourth switching element 20D and the third portion 25C.

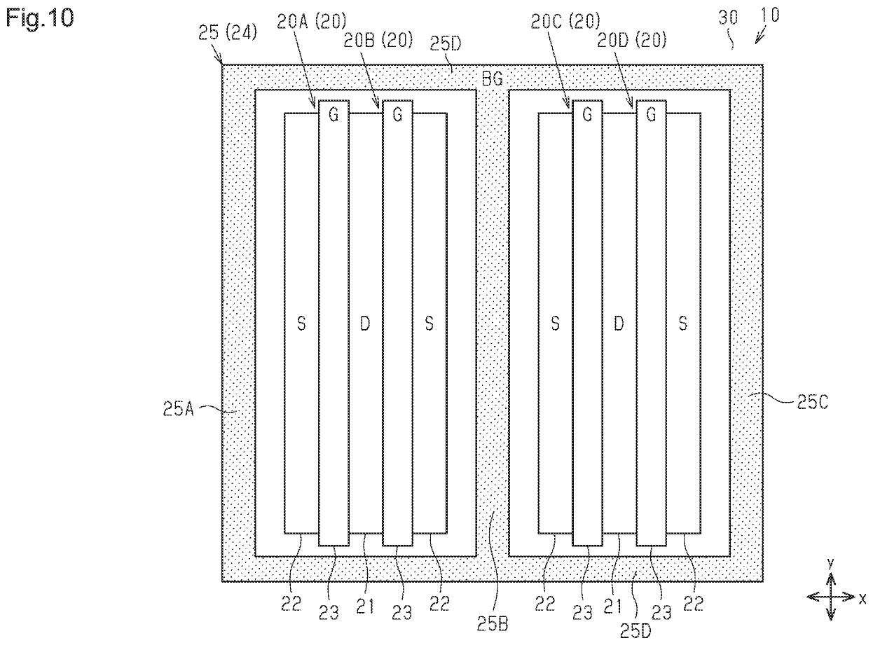

In the above embodiment, as shown in FIG. 10, the drain 21 of the first switching element 20A is a common drain shared by the drain 21 of the second switching element 20B. The common drain corresponds to a first drain. The third switching element 20C and the fourth switching element 20D may also share a common drain 21. The common drain of the third switching element 20C and the fourth switching element 20D corresponds to a second drain. With this configuration, the protection element 10 can have a smaller area than when the switching elements 20A to 20D each include a separate drain 21.

As shown in FIG. 10, in the first switching element 20A and the second switching element 20B, the source 22 of the first switching element 20A, the gate 23 of the first switching element 20A, the common drain 21, the gate 23 of the second switching element 20B, and the source 22 of the second switching element 20B are arranged in this order from the first portion 25A toward the second portion 25B in the x-direction.

In the third switching element 20C and the fourth switching element 20D, the source 22 of the third switching element 20C, the gate 23 of the third switching element 20C, the common drain 21, the gate 23 of the fourth switching element 20D, and the source 22 of the fourth switching element 20D are arranged in this order from the second portion 25B toward the third portion 25C in the x-direction.

In the above embodiment, at least one of the two fourth portions 25D may be omitted from the back gate guard ring 25.

In the above embodiment, the protection element 10 protects the two switching elements 201 and 202. This is not a limitation. For example, the protection element 10 may protect an LSI. The protection element 10 may be any protection element that protects an electronic component such as a semiconductor device.

Clauses

Technical concepts that can be understood from the above embodiment and the modified examples will now be described.

Clause 1

A protection element, including:
switching elements formed by n-type MOSFETs and arranged in a single line in a state connected in parallel to each other;
a back gate guard ring surrounding the switching elements, where:
the switching elements include a first switching element and a second switching element;
the back gate guard ring includes a first portion and a second portion;
the first portion, the first switching element, the second switching element, and the second portion are arranged in this order;
a source of the first switching element is located closer to the first portion than a gate of the first switching element; and
a source of the second switching element is located closer to the second portion than a gate of the second switching element.

Clause 2

The protection element according to clause 1, where a distance between the source of the first switching element and the first portion is equal to a distance between a source of the second switching element and the second portion.

Clause 3

The protection element according to clause 1 or 2, where the switching elements each include a separate drain.

Clause 4

The protection element according to clause 3, where the drain, the gate, and the source of each of the switching elements are arranged in an arrangement direction of the switching elements.

Clause 5

The protection element according to clause 4, where:
the source, the gate, and the drain of the first switching element are arranged in this order from the first portion toward the second portion in an arrangement direction of the first switching element and the second switching element; and
the drain, the gate, and the source of the second switching element are arranged in this order from the first portion toward the second portion in the arrangement direction of the first switching element and the second switching element.

Clause 6

The protection element according to clause 1 or 2, where a drain of the first switching element is a common drain shared by a drain of the second switching element.

Clause 7

The protection element according to clause 6, where the source, the gate, and the common drain of each of the switching elements are arranged in an arrangement direction of the switching elements.

Clause 8

The protection element according to clause 7, where in the first switching element and the second switching element, the source of the first switching element, the gate of the first switching element, the common drain, the gate of the second switching element, and the source of the second switching element are arranged in this order from the first portion toward the second portion in the arrangement direction of the switching elements.

### REFERENCE SIGNS LIST

10) protection element
20) switching element
20A) first switching element
20B) second switching element
20C) third switching element
20D) fourth switching element
21) drain
22) source
23) gate
25) back gate guard ring
25A) first portion
25B) second portion
25C) third portion

1. A protection element, comprising:
switching elements formed by n-type MOSFETs and arranged in one direction in a state connected in parallel to each other; and
a back gate guard ring surrounding the switching elements, wherein:
the switching elements include a first switching element, a second switching element, a third switching element, and a fourth switching element that are arranged in this order;
the back gate guard ring includes
a first portion located adjacent to the first switching element at an opposite side of the second switching element,
a second portion located between the second switching element and the third switching element, and
a third portion located adjacent to the fourth switching element at an opposite side of the second switching element;
a source of the first switching element is located closer to the first portion than a gate of the first switching element; and
a source of the second switching element is located closer to the second portion than a gate of the second switching element; and
a source of the third switching element is located closer to the second portion than a gate of the third switching element.

2. The protection element according to claim 1, wherein a source of the fourth switching element is located closer to the third portion than a gate of the fourth switching element.

3. The protection element according to claim 2, wherein a distance between the source of the first switching element and the first portion, a distance between the source of the second switching element and the second portion, a distance between the source of the third switching element and the second portion, and a distance between the source of the fourth switching element and the third portion are equal to one another.

4. The protection element according to claim 1, wherein the second portion has the form of a single strip extending in a direction orthogonal to an arrangement direction of the switching elements, in plan view.

5. The protection element according to claim 1, the switching elements each include a separate drain.

6. The protection element according to claim 5, wherein the drain, the gate, and the source of each of the switching elements are arranged in an arrangement direction of the switching elements.

7. The protection element according to claim 6, wherein:
the source, the gate, and the drain of the first switching element are arranged in this order from the first portion toward the second portion in the arrangement direction of the switching elements;
the drain, the gate, and the source of the second switching element are arranged in this order from the first portion toward the second portion in the arrangement direction of the switching elements;
the source, the gate, and the drain of the third switching element are arranged in this order from the second portion toward the third portion in the arrangement direction of the switching elements; and
the drain, the gate, and the source of the fourth switching element are arranged in this order from the second portion toward the third portion in the arrangement direction of the switching elements.

8. The protection element according to claim 1, wherein:
a drain of the first switching element and a drain of the second switching element share a common first drain; and
a drain of the third switching element and a drain of the fourth switching element share a common second drain.

9. The protection element according to claim 8, wherein the source, the gate, the first drain, and the second drain of each of the switching elements are arranged in the arrangement direction of the switching elements.

10. The protection element according to claim 9, wherein:
in the first switching element and the second switching element, the source of the first switching element, the gate of the first switching element, the first drain, the gate of the second switching element, and the source of the second switching element are arranged in this order from the first portion toward the second portion in the arrangement direction of the switching elements; and
in the third switching element and the fourth switching element, the source of the third switching element, the gate of the third switching element, the second drain, the gate of the fourth switching element, and the source of the forth switching element are arranged in this order from the second portion toward the third portion in the arrangement direction of the switching elements.
